(19) United States
(12) Patent Application Publication
(10) Pub. No.: US 2025/0374565 A1
(43) Pub. Date: Dec. 4, 2025

(54) MIM CAPACITOR STRUCTURE AND FABRICATING METHOD OF THE SAME

(71) Applicant: UNITED MICROELECTRONICS CORP., Hsin-Chu City (TW)

(72) Inventors: Yao-Hsien Chung, Tainan city (TW); Tai-Cheng Hou, Tainan city (TW); Da-Jun Lin, Kaohsiung City (TW); Fu-Yu Tsai, Tainan city (TW); Bin-Siang Tsai, Changhua County (TW)

(73) Assignee: UNITED MICROELECTRONICS CORP., Hsin-Chu City (TW)

(21) Appl. No.: 18/777,523

(22) Filed: Jul. 18, 2024

(30) Foreign Application Priority Data
May 28, 2024 (TW) 113119712

(51) Int. Cl. H10D 1/00; H10D 1/68

(52) U.S. Cl. CPC H10D 1/042; H10D 1/716

(57) ABSTRACT

A capacitor structure includes a substrate. A recess is disposed in the substrate, wherein the recess includes a sidewall and a bottom. A pillar is disposed in the recess and contacts the bottom of the recess. The pillar is formed by stacking a silicon nitride-based material layer and a silicon oxide-based material layer cyclically and alternately. The silicon oxide-based material layer includes a first sidewall. The first sidewall is arc-shaped. An MIM capacitor continuously covers and contacts the pillar, the sidewall of the recess and the bottom of the recess.

### BACKGROUND OF THE INVENTION

### 1. Field of the Invention

The present invention relates to a metal-insulator-metal (MIM) capacitor structure and a fabricating method of the same, in particular to an MIM capacitor structure with an increased electrode area and a fabricating method of the same.

### 2. Description of the Prior Art

In recent years, with the development of semiconductor integrated circuit process technology, the width of components manufactured on semiconductor substrates has gradually become smaller, and the density of integrated circuits per unit area has also become higher. However, due to the increase in the density of memory cell, the space for the capacitor becomes smaller, so it is necessary to develop capacitors with small size but high capacitance.

Under high density, sufficient capacitance can be obtained by using MIM capacitors. This is one of the advantages of MIM capacitors. MIM capacitors are not only used to filter noise in radio frequency circuits, or in digital circuits. They are also widely used in general integrated circuit and circuit board manufacturing processes.

### SUMMARY OF THE INVENTION

In view of this, the present invention provides an MIM capacitor structure with increased capacitance per unit area.

According to a preferred embodiment of the present invention, an MIM capacitor structure includes a substrate. A recess is disposed in the substrate, wherein the recess includes a sidewall and a bottom. A pillar is disposed in the recess and contacts the bottom of the recess, wherein the pillar is formed by stacking a silicon nitride-based material layer and a silicon oxide-based material layer cyclically and alternately. The silicon oxide-based material layer includes a first sidewall, and the first sidewall has an arc-shaped profile. An MIM capacitor continuously covers and contacts the pillar, the sidewall of the recess and the bottom of the recess.

According to another preferred embodiment of the present invention, a fabricating method of an MIM capacitor includes providing a substrate. The substrate is etched to form a recess. The recess includes a sidewall and a bottom. A silicon nitride-based material layer and a silicon oxide-based material layer are formed to be stacked cyclically and alternately to form a composite layer, wherein the composite layer covers the sidewall of the recess and the bottom of the recess. Next, the composite layer is patterned to form at least one pillar. Subsequently, a selective etching is performed to etch the silicon oxide-based material layer of the pillar. After the selective etching, an MIM capacitor is formed to continuously cover and contact the pillar, the sidewall of the recess, the bottom of the recess and a top surface of the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a fabricating method of an MIM capacitor structure according to a preferred embodiment of the present invention, wherein:

FIG. 1 depicts a recess and a composite layer on a substrate;

FIG. 2 is a fabricating stage following FIG. 1;

FIG. 3 is a fabricating stage following FIG. 2;

FIG. 4 is a fabricating stage following FIG. 3;

FIG. 5 is a fabricating stage following FIG. 4; and

FIG. 6 is a fabricating stage following FIG. 5;

FIG. 7 depicts a composite layer of an MIM capacitor structure according to another preferred embodiment of the present invention.

FIG. 8 shows a top view of an MIM capacitor structure according to a preferred embodiment of the present invention.

FIG. 9 depicts a modified embodiment of FIG. 8.

FIG. 10 depicts another modified embodiment of FIG. 8.

FIG. 11 depicts an MIM capacitor structure according to another preferred embodiment of the present invention.

FIG. 12 depicts an MIM capacitor structure according to another preferred embodiment of the present invention.

FIG. 13 depicts an MIM capacitor structure according to another preferred embodiment of the present invention.

FIG. 14 depicts an MIM capacitor structure according to another preferred embodiment of the present invention.

### DETAILED DESCRIPTION

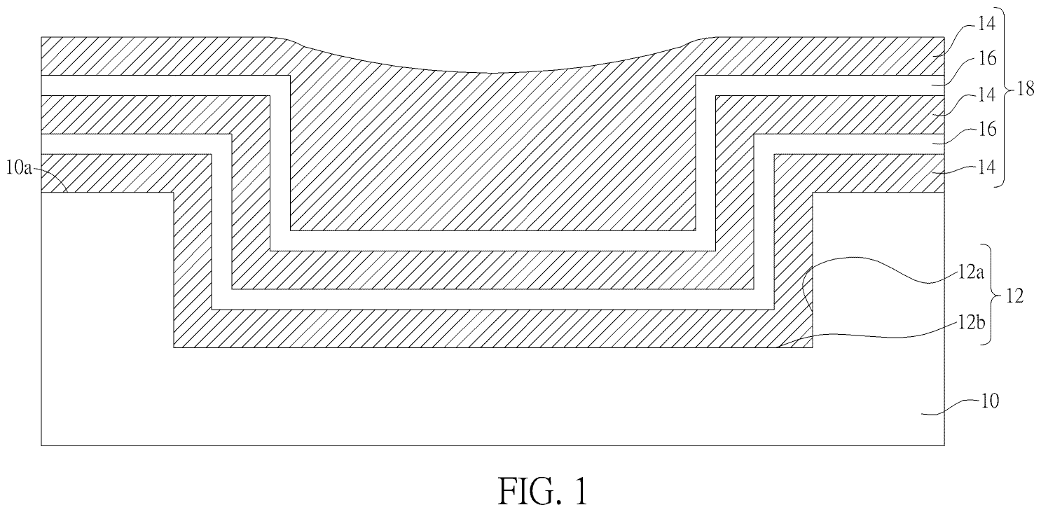

FIG. 1 to FIG. 6 depict a fabricating method of an MIM capacitor structure according to a preferred embodiment of the present invention.

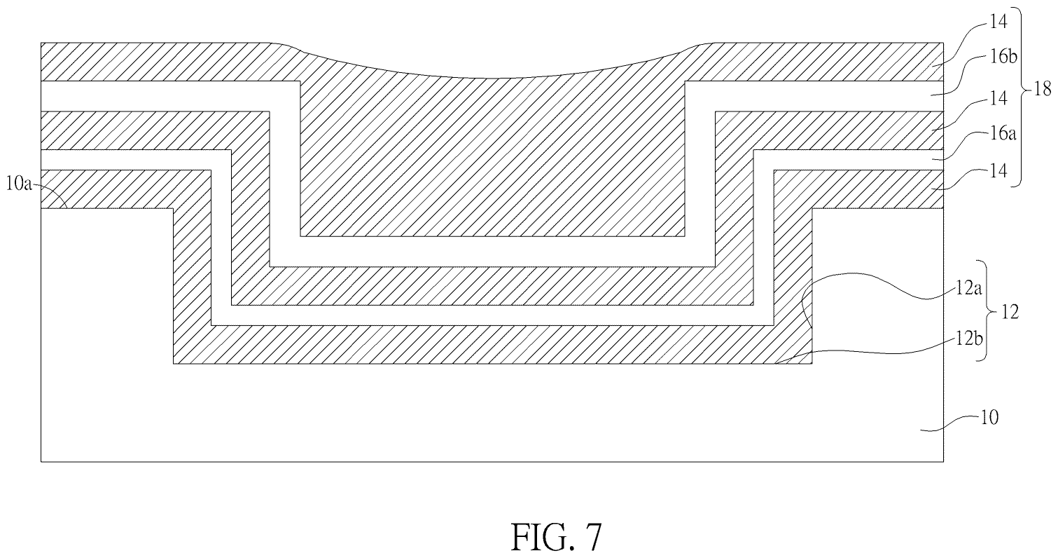

As shown in FIG. 1, a substrate 10 is provided. The substrate 10 includes a semiconductor substrate, such as a silicon substrate, an epitaxial silicon substrate, a silicon germanium substrate, a silicon carbide substrate, a silicon-on-insulator (SOI) substrate or other suitable semiconductor materials. Then, the top surface 10a of the substrate 10 is etched to the inside of the substrate 10 to form a recess 12 embedded in the substrate 10. The recess includes a sidewall 12a and a bottom 12b. Later, a silicon nitride-based material layer 14 and a silicon oxide-based material layer 16 are formed to stack alternately and cyclically in the recess 12. The silicon nitride-based material layer 14 includes Si₃N₄, SiON, SiCN, SiOCN, or any other suitable dielectric material. The silicon oxide-based material layer 16 includes SiO₂, SiOC, or any other suitable dielectric material. The silicon nitride-based material layer 14 and the silicon oxide-based material layer 16 conformably cover recess 12. The silicon nitride-based material layers 14 and the silicon oxide-based material layers 16 which are alternately stacked form a composite layer 18. That is, the composite layer 18 includes numerous silicon nitride-based material layers 14 and numerous silicon oxide-based material layers 16. The composite layer 18 conformally covers the recess 12 and the top surface of substrate 10. The silicon nitride-based material layer 14 and the silicon oxide-based material layer 16 can be stacked alternately several times. Because the silicon nitride-based material layer 14 and the silicon oxide-based material layer 16 are continuously stacked alternately, there are no other material layer between the silicon nitride-based material layer 14 and the silicon oxide-based material layer 16. The alternating stacking sequence may include forming the silicon oxide-based material layer 16 first followed by forming the silicon nitride-based material layer 14. On the other hand, the silicon nitride-based material layer 14 may be formed before the silicon oxide-based material layer 16 is formed. The total number of layers of silicon nitride-based material layer 14 and silicon oxide-based material layer 16 can be adjusted according to product requirements. For example, according to FIG. 1, the silicon nitride-based material layer 14 is formed first. The total number of stacked layers (silicon oxide-based material layer 16 and the silicon nitride-based material layer 14) is 5. The silicon nitride-based material layer 14 and the silicon oxide-based material layer 16 may be formed by a chemical vapor deposition, a physical vapor deposition or atomic layer deposition. In the embodiment shown in FIG. 1, each of the silicon oxide-based material layers 16 has the same thickness. In addition, a thickness of the bottommost silicon nitride-based material layer 14 is greater than a thickness of the bottommost silicon oxide-based material layer 16. According to another preferred embodiment, as shown in FIG. 7, there are at least two silicon oxide-based material layers having thicknesses different from each other. For example, the thickness of the silicon oxide-based material layer 16b is greater than the thickness of silicon oxide-based material layer 16a.

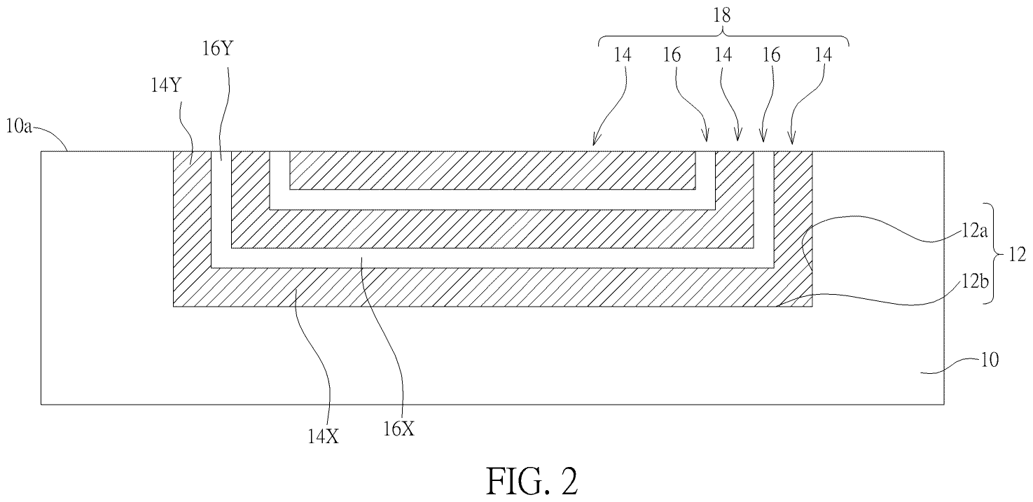

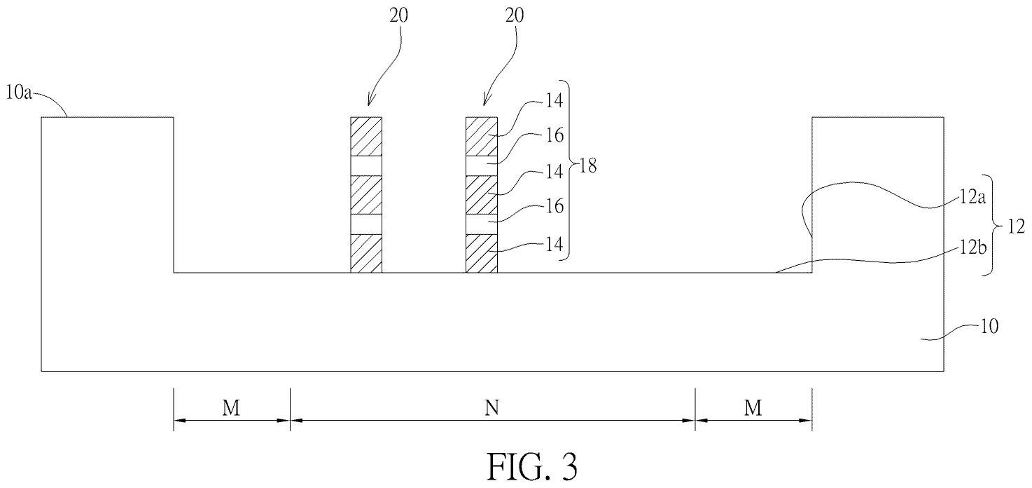

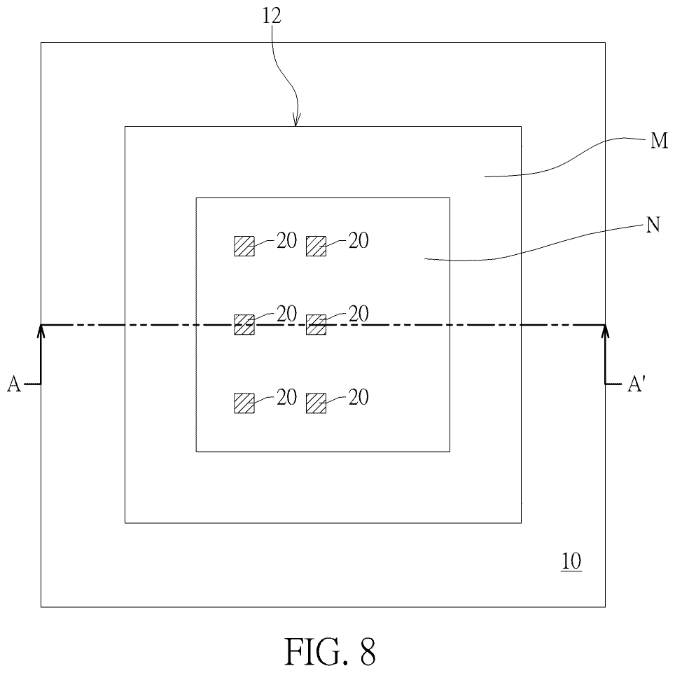

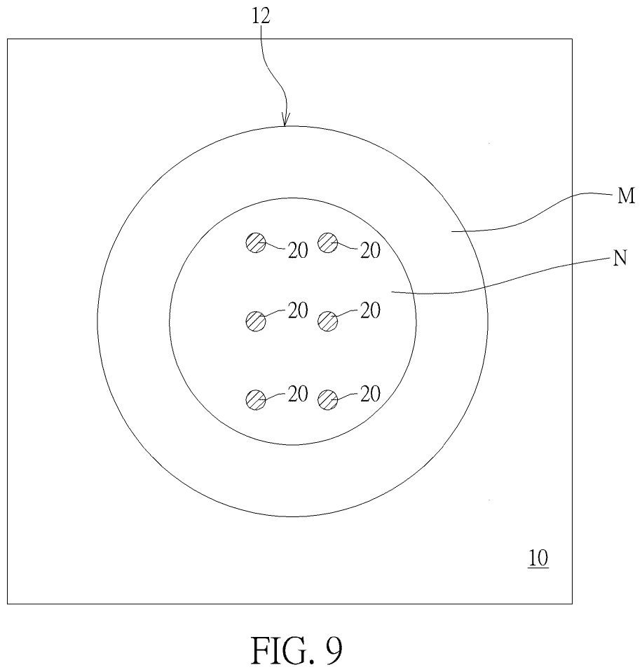

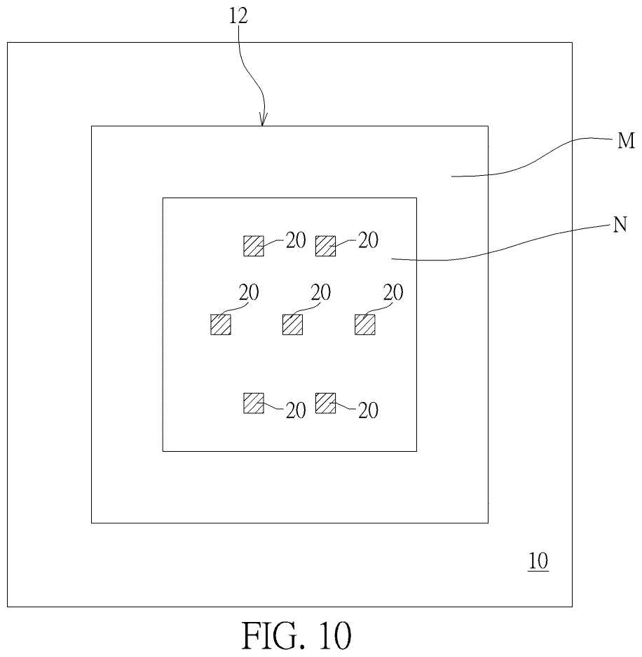

As shown in FIG. 2, the composite layer 18 is planarized to make the top surface of the composite layer 18 to be aligned with the top surface 10a of the substrate 10. The planarization can be performed by a chemical mechanical polishing. As shown in FIG. 3, the composite layer 18 is patterned to form at least one pillar 20 disposed in the recess 12. The pillar 20 contacts the substrate 10. The method of patterning the composite layer 18 includes exposure, development and etching processes. Please refer to FIG. 2. Because both of the silicon nitride-based material layer 14 and the silicon oxide-based material layer 16 cover the recess 12 conformally, the profile of the silicon nitride-based material layer 14 and the profile of the silicon oxide-based material layer 16 form an outline like the recess 12. In details, the silicon nitride-based material layer 14 and the silicon oxide-based material layer 16 respectively have horizontal portions 14X/16X and vertical portions 14Y/16Y. The vertical portions 14Y/16Y are along the sidewall 12a of the recess 12, and the horizontal portions 14x/16X are along the bottom 12b of the recess 12. Because the pillar 20 requires the structure of the horizontal portions 14x/16X, the vertical portions 14Y/16Y is removed during patterning the composite layer 18. Furthermore, the composite layer 18 contacting the sidewall 12a of recess 12 is removed. FIG. 8 shows a top view of a substrate, a pillar and a recess, wherein FIG. 3 is a sectional view taken along line AA′ in FIG. 8. Please refer to FIG. 2 and FIG. 8, a blank area M is formed by removing the vertical portions 14Y/16Y during patterning the composite layer 18. There is no pillar 20 in the blank area M. Moreover, in FIG. 8, when seeing from the top view, the recess 12 is rectangular, and the pillar 20 is also rectangular. Pillars 20 are arranged in an array. FIG. 9 and FIG. 10 are modified embodiment of FIG. 8. As shown in FIG. 9, when seeing from a top view, the recess 12 is circular and the pillar 20 is also circular. As shown in FIG. 10, the pillars 20 may be in a staggered arrangement. However, the shapes of the recess 12 and the pillar 20 do not necessarily have to be the shapes shown in FIG. 8 and FIG. 9. In other embodiments, when the recess 12 is rectangular, the pillar 20 may be circular, or when the recess 12 is circular, the pillar 20 may be rectangular.

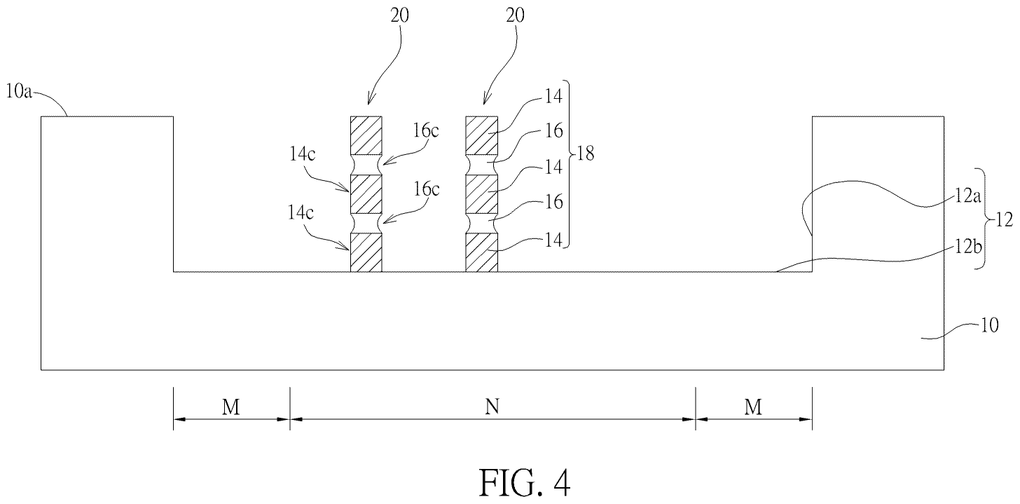

As shown in FIG. 4, FIG. 4 shows steps in continuous of FIG. 3. A selective etching is performed to etch the silicon oxide-based material layer 16 in each pillar 20. During selective etching, the substrate 10 and the silicon nitride-based material layer 14 is not etched. The selective etching can include a chemical oxide removal (COR) process or a wet etching. After the selective etching, the sidewall 16c of the silicon oxide-based material layer 16 is etched to become an arc-shaped profile. The arc-shaped profile is concave toward the center of the pillar 20. The sidewall 14c of the silicon nitride-based material layer 14 remains flat.

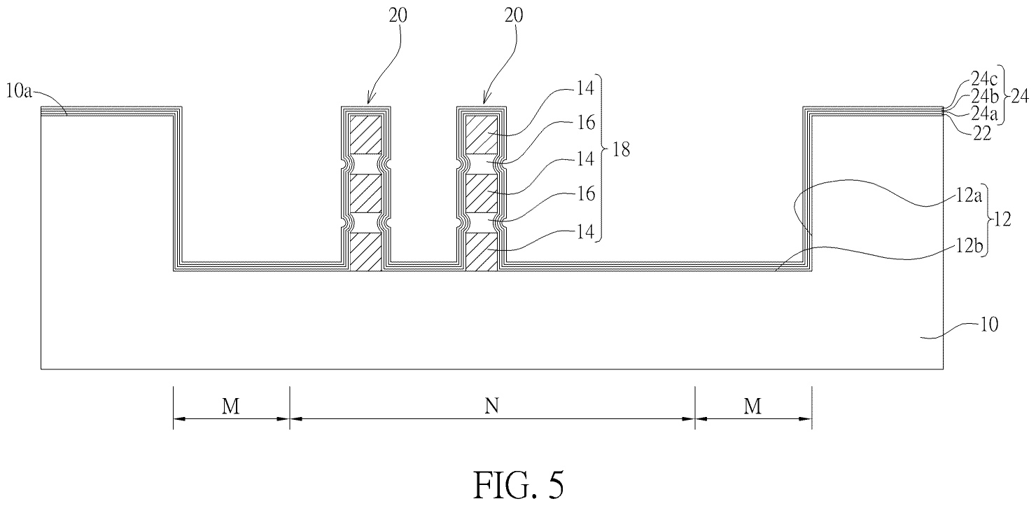

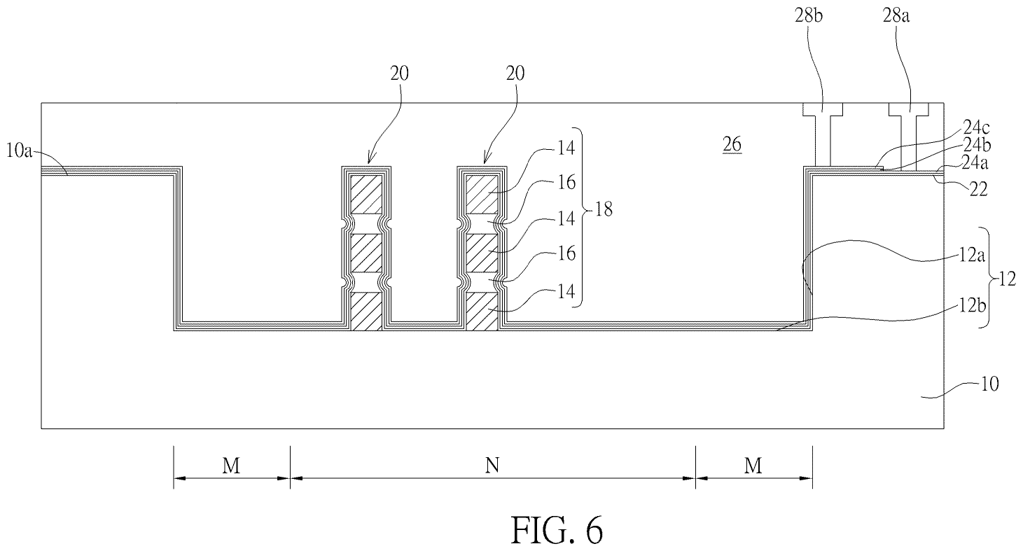

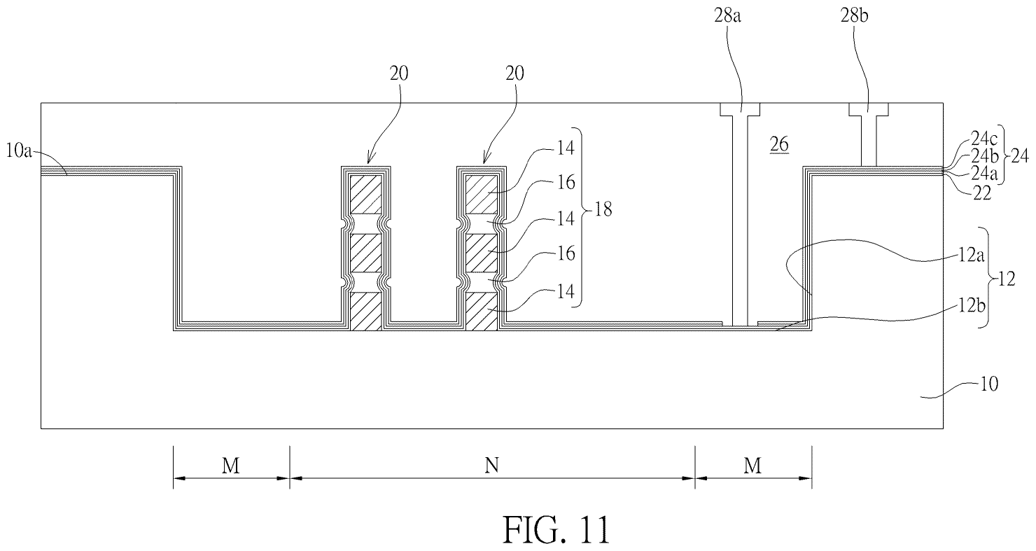

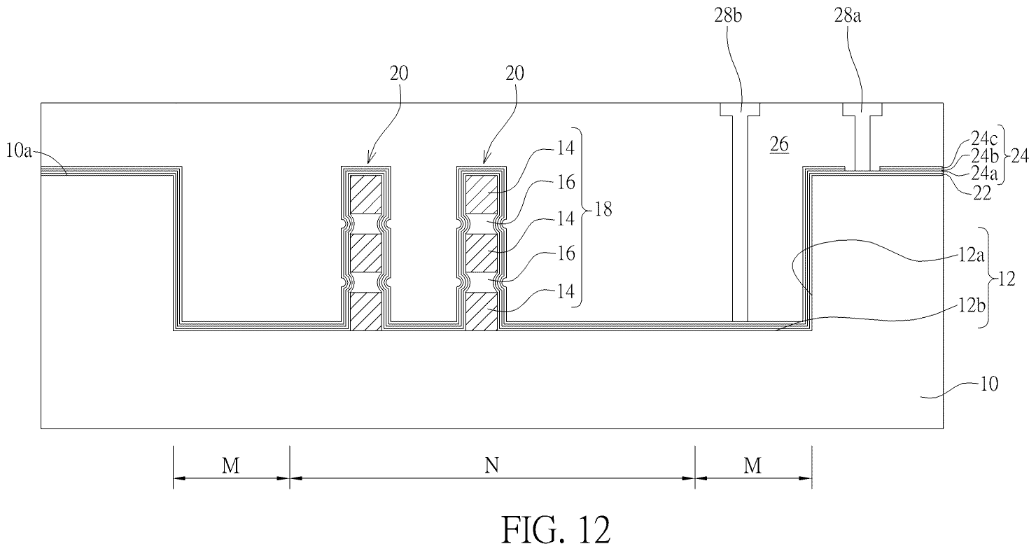

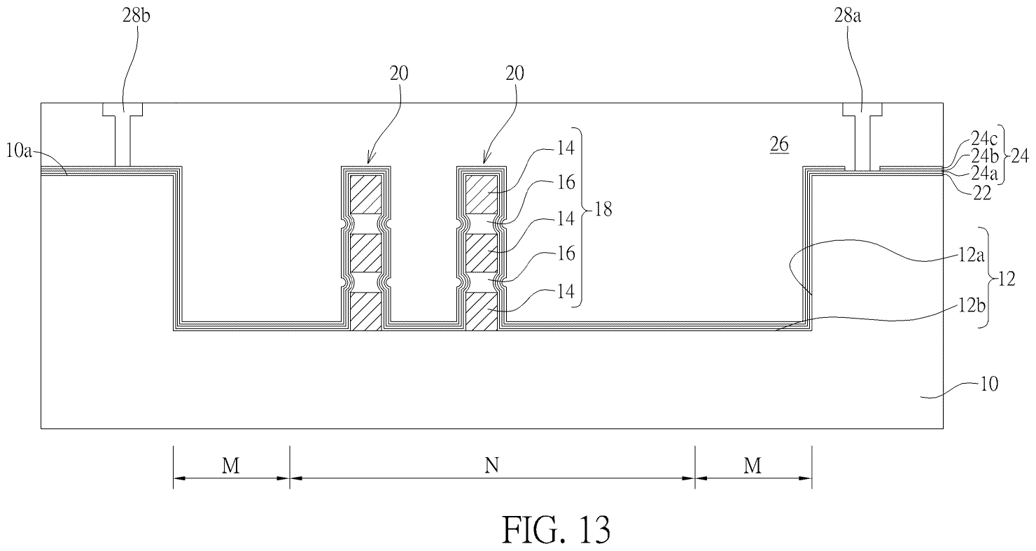

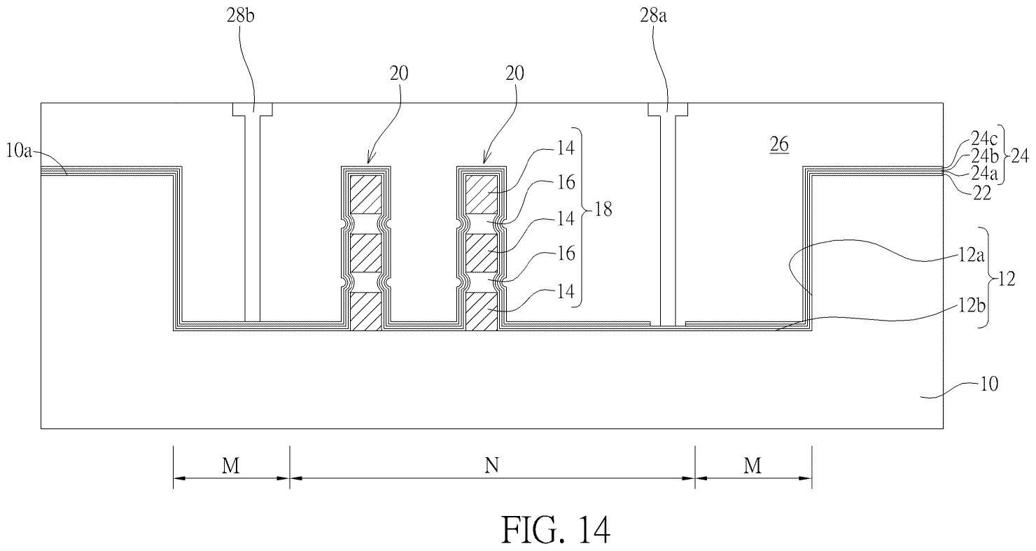

As shown in FIG. 5, a silicon oxide liner 22 is formed to conformally and continuously cover the sidewall 12a and the bottom 12b of the recess 12 and each pillar 20. The exposed surface of each pillar 20 is contacted and covered by the silicon oxide liner 22. Later, an MIM capacitor 24 is then formed to cover the silicon oxide liner 22 conformally. The MIM capacitor 24 includes a first electrode 24a, a capacitor dielectric layer 24b and a second electrode 24c. In details, the MIM capacitor 24 completely covers each pillar 20, the sidewall 12a of the recess 12 and the bottom 12b of the recess 12. Since the silicon oxide-based material layer 16 has an arc-shaped profile, the MIM capacitor 24 thus increases the coverage of the first electrode 24a and the second electrode 24c by covering the arc-shaped profile. Therefore, capacitance is increased. Moreover, the capacitor dielectric layer 24b is sandwiched between the first electrode and the second electrode 24c. The formation sequence of the first electrode 24a, the capacitor dielectric layer 24b and the second electrode 24c is in the listed order as follows: the first electrode 24a, the capacitor dielectric layer 24b, and the second electrode 24c. As shown in FIG. 6, part of the second electrode 24c and the capacitor dielectric layer 24b are removed to expose part of the first electrode 24a located on the top surface 10a of the substrate 10 outside the recess 12. Next, a dielectric layer 26 is formed to fill the recess 12 and cover the MIM capacitor 24 and the top surface 10a of the substrate 10. Later, a first plug 28a and a second plug 28b are formed. The first plug 28a penetrates the dielectric layer 26 to contact the first electrode 24a, and the second plug 28b penetrates the dielectric layer 26 to contact the second electrode 24c. Now, the MIM capacitor structure 100 of the present invention is completed. In the embodiment of FIG. 6, the first plug 28a and the second plug 28b are located on the top surface 10a of the substrate 10 outside the recess 12 and the first plug 28a and the second plug 28b are adjacent to each other. However, according to other preferred embodiments of the present invention, the first plug 28a and the second plug 28b may be disposed in other positions, as long as the first plug 28a contacts the first electrode 24a and the second plug 28b contacts the second electrode 24c. For example, as shown in FIG. 11, the first plug 28a is located within the recess 12, and the first plug 28a is located in the blank area M. The second plug 28b is located on the top surface 10a of the substrate 10 outside the recess 12, but not limited to it. The first plug 28a may also be disposed in the pillar area N. Moreover, the first plug 28a and the second plug 28b are disposed on the same side of the pillar 20. As shown in FIG. 12, the second plug 28b is disposed within the recess 12, and within the blank area M, but not limited to it. The second plug 28b may also be disposed in the pillar area N. The first plug 28a is located on the top surface 10a of the substrate 10 outside the recess 12. Besides, the first plug 28a and the second plug 28b are disposed on the same side of the pillar 20. As shown in FIG. 13, the first plug 28a and the second plug 28b are both located outside the recess 12 and on the top surface 10a of the substrate 10. The first plug 28a and the second plug 28b are respectively disposed on opposite sides of the recess 12. As shown in FIG. 14, the first plug 28a and the second plug 28b are both located within the recess 12. The first plug 28a is disposed in the pillar area N, and the second plug 28b is disposed in the blank area M. The first plug 28a and the second plug 28b are respectively disposed on opposite sides of the pillars 20.

FIG. 6 shows an MIM capacitor structure fabricated according to the aforementioned process. As shown in FIG. 6, an MIM capacitor structure 100 includes a substrate 10. A recess 12 is disposed in the substrate 10. The recess 12 includes a sidewall 12a and a bottom 12b. Numerous pillars 20 are disposed in the recess 12 and contact the bottom 12b of the recess 12. Each pillar 20 is formed by stacking a silicon nitride-based material layer 14 and a silicon oxide-based material layer 16 cyclically and alternately. The silicon oxide-based material layer 16 has a sidewall 16c (Please refer to FIG. 4). The sidewall 16c has an arc-shaped profile. The arc-shaped profile is concave toward the center of the pillar 20. An MIM capacitor 24 continuously covers and contacts each pillar 20, the sidewall 12a and the bottom 12b of the recess 12. The MIM capacitor 24 also extends to the top surface 10a of the substrate 10. A dielectric layer 26 fills the recess 12 and covers the MIM capacitor 24 and the top surface 10a of the substrate 10. The MIM capacitor 24 includes a first electrode 24a, a capacitor dielectric layer 24b and a second electrode 24c. The capacitor dielectric layer 24b is sandwiched between the first electrode 24a and the second electrode 24c. The first plug 28a penetrates through the dielectric layer 26 to contact the first electrode 24a, and the second plug 28b penetrates through the dielectric layer 26 to contact the second electrode 24c.

In addition, please refer to FIG. 8. The recess 12 is divided into a blank area M and a pillar area N. The blank area M surrounds the pillar area N. Each pillar 20 is disposed in the pillar area N. There is not any pillar 20 within the blank area M.

According to a preferred embodiment of the present invention, the depth of the recess 12 may be 6 micrometers, 9 micrometers or 12 micrometers. A thickness of a single silicon nitride-based material layer 14 is preferably between 500 and 600 nanometers. A thickness of a single silicon oxide-based material layer 16 is preferably between 500 and 600 nanometers. Moreover, the first electrode 24a and the second electrode 24c may respectively include tantalum nitride, titanium nitride, tantalum, or titanium. The capacitor dielectric layer 24b includes aluminum oxide, zirconium oxide, barium strontium titanate (BST), lead zirconate titanate (PZT), zirconium silicate (ZrSiO₄), hafnium silicon oxide (HfSiO₂), hafnium silicon oxynitride (HfSiON), tantalum oxide or a combination thereof. The dielectric layer 26 includes silicon oxide, silicon nitride or other low dielectric constant materials.

In the present invention, silicon nitride-based material layers and silicon oxide-based material layers are alternately stacked in the recess of the substrate. Next, the alternately stacked silicon nitride-based material layers and silicon oxide-based material layers are etched to form pillars. Later, surfaces of the silicon oxide-based material layers are selective etched to form arc-shaped profiles. The arc-shaped profiles can help to increase the coverage of the MIM capacitor, thereby increasing the capacitance per unit area.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A metal-insulator-metal (MIM) capacitor structure, comprising:
a substrate;
a recess disposed in the substrate, wherein the recess comprises a sidewall and a bottom;
a pillar disposed in the recess and contacting the bottom of the recess, wherein the pillar is formed by stacking a silicon nitride-based material layer and a silicon oxide-based material layer cyclically and alternately, the silicon oxide-based material layer comprises a first sidewall, and the first sidewall has an arc-shaped profile; and
an MIM capacitor continuously covering and contacting the pillar, the sidewall of the recess and the bottom of the recess.

2. The MIM capacitor structure of claim 1, wherein the arc-shaped profile is concave toward the center of the pillar.

3. The MIM capacitor structure of claim 1, wherein the silicon nitride-based material layer has a second sidewall, and the second sidewall is a flat surface.

4. The MIM capacitor structure of claim 1, further comprising a plurality of the pillars disposed in the recess and contacting the bottom of the recess, wherein the MIM capacitor continuously covers and contacts the plurality of pillars.

5. The MIM capacitor structure of claim 1, wherein a thickness of the bottommost silicon nitride-based material layer is greater than a thickness of the bottommost silicon oxide-based material layer.

6. The MIM capacitor structure of claim 1, wherein the silicon oxide-based material layer and the silicon nitride-based material layer are alternately stacked to form a plurality of silicon oxide-based material layers and a plurality of silicon nitride-based material layers, and a thickness of each of the plurality of silicon oxide-based material layers is different.

7. The MIM capacitor structure of claim 1, further comprising a dielectric layer filling in the recess, covering the MIM capacitor and a top surface of the substrate.

8. The MIM capacitor structure of claim 1, wherein the MIM capacitor comprises:
a first electrode, a capacitor dielectric layer and a second electrode stacked from bottom to top in sequence.

9. The MIM capacitor structure of claim 8, further comprising:
a first plug disposed within the recess and embedded in the dielectric layer, wherein the first plug contacts the first electrode of the MIM capacitor; and
a second plug disposed on a top surface of the substrate outside the recess and embedded in the dielectric layer, wherein the second plug contacts the second electrode of the MIM capacitor, and the first plug and the second plug are at a same side of the pillar.

10. The MIM capacitor structure of claim 8, further comprising:
a second plug disposed within the recess and embedded in the dielectric layer, wherein the second plug contacts the second electrode of the MIM capacitor; and
a first plug disposed on a top surface of the substrate outside the recess and embedded in the dielectric layer, wherein the first plug contacts the first electrode of the MIM capacitor.

11. The MIM capacitor structure of claim 8, further comprising:
a first plug disposed on a top surface of the substrate outside the recess and embedded in the dielectric layer, wherein the first plug contacts the first electrode of the MIM capacitor; and
a second plug disposed on the top surface of the substrate outside the recess and embedded in the dielectric layer, wherein the second plug contacts the second electrode of the MIM capacitor, and the first plug and the second plug are at opposite sides of the recess.

12. The MIM capacitor structure of claim 8, further comprising:
a first plug disposed within the recess and embedded in the dielectric layer, wherein the first plug contacts the first electrode of the MIM capacitor; and
a second plug disposed within the recess and embedded in the dielectric layer, wherein the second plug contacts the second electrode of the MIM capacitor, and the first plug and the second plug are at opposite sides of the pillar.

13. The MIM capacitor structure of claim 8, further comprising:
a first plug disposed on a top surface of the substrate outside the recess and embedded in the dielectric layer, wherein the first plug contacts the first electrode of the MIM capacitor; and
a second plug disposed on the top surface of the substrate outside the recess and embedded in the dielectric layer, wherein the second plug contacts the second electrode of the MIM capacitor, and the first plug is adjacent to the second plug.

14. A fabricating method of a metal-insulator-metal (MIM) capacitor, comprising:
providing a substrate;
etching the substrate to form a recess, wherein the recess comprises a sidewall and a bottom;
forming a silicon nitride-based material layer and a silicon oxide-based material layer stacked cyclically and alternately to form a composite layer, wherein the composite layer covers the sidewall of the recess and the bottom of the recess;
patterning the composite layer to form at least one pillar;
performing a selective etching to etch the silicon oxide-based material layer of the pillar; and
after the selective etching, forming an MIM capacitor to continuously cover and contact the pillar, the sidewall of the recess, the bottom of the recess and a top surface of the substrate.

15. The fabricating method of an MIM capacitor of claim 14, wherein the selective etching comprises a chemical oxide removal (COR) process or a wet etching.

16. The fabricating method of an MIM capacitor of claim 14, wherein after the selective etching, a sidewall of the silicon oxide-based material layer forms an arc-shaped profile which is concave toward the center of the pillar.

17. The fabricating method of an MIM capacitor of claim 14, further comprising before patterning the composite layer, the composite layer is planarized to make a top surface of the composite layer to be aligned with the top surface of the substrate.

18. The fabricating method of an MIM capacitor of claim 14, wherein a thickness of the bottommost silicon nitride-based material layer is greater than a thickness of the bottommost silicon oxide-based material layer.

19. The fabricating method of an MIM capacitor of claim 14, wherein the composite layer comprises a plurality of silicon oxide-based material layers and a plurality of silicon nitride-based material layers, and a thickness of each of the plurality of silicon oxide-based material layers is different.

20. The fabricating method of an MIM capacitor of claim 14, further comprising after forming the MIM capacitor, a dielectric layer is formed to fill the recess and cover the MIM capacitor and the top surface of the substrate.
